(19) United States
(12) Patent Application Publication
(10) Pub. No.: US 2017/0227811 A1
(43) Pub. Date: Aug. 10, 2017

(54) OPTICAL DEVICE PACKAGE, OPTICAL SWITCH, AND METHOD FOR MANUFACTURING OPTICAL DEVICE PACKAGE

(71) Applicant: FUJIKURA LTD., Tokyo (JP)

(72) Inventor: Takuya ODA, Sakura-shi (JP)

(73) Assignee: FUJIKURA LTD., Tokyo (JP)

(21) Appl. No.: 15/502,895

(22) PCT Filed: Mar. 22, 2016
(86) PCT No.: PCT/JP2016/059025

§ 371 Date: Feb. 9, 2017

(30) Foreign Application Priority Data
Jun. 16, 2015 (JP) 2015-121126

(51) Int. Cl. G02F 1/1333; G02F 1/1335; H01L 31/0203; G02F 1/31; H01L 27/146

(52) U.S. Cl. CPC G02F 1/133308; G02F 1/31; H01L 27/14618; H01L 27/14683; H01L 31/0203; G02F 1/133305; G02F 1/133553; G02F 2201/50; G02F 2001/133311; G02F 2001/133331; G02F 2203/02; G02F 2202/105

(57) ABSTRACT

The present invention relates to an optical device package in which a deterioration in performance of an optical device is suppressed which deterioration may be caused by dust on a light path. An optical device package (10) including a case (13, 14) in which an optical device (11) is sealed includes a lid (13) having an optical window (13a) which transmits light, and the optical device (11) is connected to the lid (13) such that at least part of an effective region (Ae) of the optical device (11) overlaps with the optical window (13a).

### TECHNICAL FIELD

The present invention relates to an optical device package including a case in which an optical device is sealed.

### BACKGROUND ART

There has been known an optical device package including a case in which an optical device of various types is sealed.

Patent Literature 1 discloses a solid-state image pickup device including a case which is constituted by a base substrate, a resin frame, and a transparent plate and in which a solid-state image pickup element which receives light transmitted by the transparent plate is sealed. In the solid-state image pickup device, the solid-state image pickup element is placed on an upper surface of the base substrate.

According to the solid-state image pickup device including the case in which the solid-state image pickup element is sealed, an optical performance of the solid-state image pickup device may be deteriorated by dust which has entered the case before the sealing or has been generated in the case after the sealing. For example, when the dust is adhered to a light receiving surface of the solid-state image pickup element or to the transparent plate, the dust blocks a light path of light received by the solid-state image pickup element, so that the optical performance of the solid-state image pickup device is deteriorated.

As a technique for preventing generation of dust in the case, Patent Literature 2 discloses an airtight-sealing semiconductor device including a case which is constituted by a base and a sealing glass and in which a chip is sealed. In the airtight-sealing semiconductor device, the chip is provided on a bottom of a cavity (in the case) provided on the base and is embedded in a light-transmitting resin layer.

### CITATION LIST

### Patent Literature

Patent Literature 1

Japanese Patent Application Publication, Tokukaihei, No. 10-144898 (Publication date: May 29, 1998)

Patent Literature 2

Japanese Patent Application Publication, Tokukaihei, No. 6-53359 (Publication date: Feb. 25, 1994)

### SUMMARY OF INVENTION

### Technical Problem

Even in the airtight-sealing semiconductor device disclosed in Patent Literature 2, there is still a possibility that dust may enter the case before the case is filled with a light-transmitting resin (e.g., at the time of wire bonding).

In a case where the case is filled with the light-transmitting resin layer while the dust is contained in the case, the dust may move together with the light-transmitting resin filled in the case. That is, the dust may be introduced into a formed light-transmitting resin layer and block a light path of light which enters the chip or light which exits the chip.

The present invention has been accomplished in view of the problem, and an object of the present invention is to suppress, in an optical device package including a case in which an optical device is sealed, a deterioration in performance of the optical device which deterioration may be caused by dust on a light path of light which enters the optical device or light which exits the optical device.

### Solution to Problem

In order to attain the object, an optical device package including a case in which an optical device is sealed, including a lid having an optical window which transmits light, the optical device being connected to the lid such that at least part of an effective region of the optical device overlaps with the optical window.

The configuration allows a distance between the optical device and the lid to be smaller, as compared with a case where the optical device is placed on a bottom of the case. That is, it is possible to reduce a possibility that dust enters between the optical device and the lid in a space sealed by the case. Accordingly, an optical device package in accordance with the present invention brings about an effect of suppressing, in an optical device package including a case in which an optical device is sealed, a deterioration in performance of the optical device which deterioration may be caused by dust on a light path of light which enters the optical device or light which exits the optical device.

According to a solid-state image pickup device disclosed in Patent Literature 1, a base substrate and a resin frame are provided between a solid-state image pickup element and a transparent plate. Accordingly, an error related to a relative positional relationship (e.g., a distance between the solid-state image pickup element and the transparent plate) between the solid-state image pickup element and the transparent plate is accumulation of an error generated when the solid-state image pickup element is connected to the base substrate, an error generated when the resin frame is connected to the base substrate, and an error generated when the transparent plate is connected to the resin frame. Meanwhile, with the configuration, since the optical device is connected to the lid, an error related to a relative positional relationship (e.g., a distance between the optical device and the optical window) between the optical device and the optical window is caused only by a manufacturing error generated when the optical device is connected to the lid. Accordingly, the configuration makes it easier to uniformize a light path length of light which enters the optical device or light which exits the optical device, as compared with the solid-state image pickup device disclosed in Patent Literature 1.

In order to attain the object, a method for manufacturing an optical device package including a case in which an optical device is sealed, the case including a body and a lid having an optical window which transmits light, the method including the steps of: connecting the optical device to the lid such that at least part of an effective region of the optical device overlaps with the optical window; and sealing the optical device by connecting the case to the lid to which the optical device has been connected.

With the configuration, a method for manufacturing an optical device package in accordance with an aspect of the present invention brings about an effect similar to that of an optical device package in accordance with an aspect of the present invention.

### Advantageous Effects of Invention

The present invention brings about an effect of suppressing, in an optical device package including a case in which an optical device is sealed, a deterioration in performance of the optical device which deterioration may be caused by dust on a light path of light which enters the optical device or light which exits the optical device.

### BRIEF DESCRIPTION OF DRAWINGS

(a) of FIG. 1 is an exploded perspective view illustrating a configuration of an optical device package in accordance with Embodiment 1 of the present invention. (b) of FIG. 1 is a cross-sectional view illustrating the configuration of the optical device package.

(a) of FIG. 2 is a flow chart showing a method for manufacturing the optical device package illustrated in FIG. 1. (b) of FIG. 2 is a flow chart showing in detail a step of bonding an optical device to an optical window, in the method shown in (a) of FIG. 2.

(a) of FIG. 3 is an exploded perspective view illustrating a configuration of an optical device package in accordance with Modified Example 1. (b) of FIG. 3 is a cross-sectional view illustrating the configuration of the optical device package.

FIG. 4 is a cross-sectional view illustrating a configuration of an optical device package in accordance with Modified Example 2.

(a) through (d) of FIG. 5 are cross-sectional views illustrating configurations of optical device packages in accordance with respective Modified Examples 3 through 6.

FIG. 6 is a cross-sectional view illustrating a configuration of an optical device package in accordance with Modified Example 7.

FIG. 7 is a cross-sectional view illustrating a configuration of an optical device package in accordance with Modified Example 8.

FIG. 8 is a cross-sectional view illustrating a configuration of an optical switch in accordance with Embodiment 2 of the present invention.

### DESCRIPTION OF EMBODIMENTS

### Embodiment 1

The following description will discuss, with reference to FIG. 1, an optical device package in accordance with Embodiment 1 of the present invention. (a) of FIG. 1 is an exploded perspective view illustrating a configuration of an optical device package 10 in accordance with Embodiment 1. (b) of FIG. 1 is a cross-sectional view illustrating the configuration of the optical device package 10 and is a cross-sectional view of a cross section taken along a line A-A′ illustrated in (a) of FIG. 1.

(Configuration of Optical Device Package 10)

As illustrated in FIG. 1, the optical device package 10 includes a case which is constituted by a lid 13 and a body 14 and in which an optical device 11 is sealed. The following description will discuss each of the optical device 11, the lid 13, and the body 14. The subsequent description will discuss how the optical device 11, the lid 13, and the body 14 are connected to each other.

(Optical Device)

Embodiment 1 employs, as an example of the optical device 11, a liquid crystal on silicon (LCOS) which is a reflective liquid crystal panel. In the Description, therefore, the optical device 11 is referred to as an LCOS 11 and the optical device package 10 is referred to as an LCOS package 10. Note that the optical device 11 is not limited to a reflective optical device such as the LCOS, but can be a light-receiving optical device or a light-emitting optical device. Examples of the light-receiving optical device encompass an image pickup device such as a CMOS and a light-detecting device such as a photodiode. Examples of the light-emitting optical device encompass a light-emitting diode and a laser diode (e.g., vertical cavity surface emitting laser (VCSEL)).

The LCOS 11 is configured such that on a silicone substrate, (i) a reflective mirror which is constituted by a metal thin film, (ii) a liquid crystal layer, and (iii) a cover glass are stacked in order. The cover glass is constituted by a glass layer. The configuration of the LCOS is well known, and thus, descriptions on a specific configuration of the LCOS 11 are omitted. Further, (b) of FIG. 1 does not illustrate a detailed configuration of the LCOS 11.

A surface of the LCOS 11 on which surface the cover glass is provided functions as a light receiving surface 11a. The light receiving surface 11a of the LCOS 11 is divided into two regions, i.e., an effective region Ae which is a region having an optical function and an ineffective region Aie which is a region having no optical function (see (a) of FIG. 1). In the LCOS 11, the effective region Ae (i) indicates a region in which a pixel electrode is provided on the silicone substrate and (ii) is provided in a center of the light receiving surface 11a. Meanwhile, the ineffective region Aie is provided so as to surround the effective region Ae.

According to Embodiment 1, the LCOS 11 is connected to a control substrate (not illustrated) via a flexible printed circuit (FPC) 16.

A method of connecting the LCOS 11 to the FPC 16 is not particularly limited. For example, it is possible to use a method of connecting, by wire bonding, the FPC 16 to an electrode (not illustrated) provided in the ineffective region Aie of the light receiving surface 11a of the LCOS 11. In such a case, a bonding wire can be sealed with a resin. The electrode which is used for connecting the bonding wire can be provided on the light receiving surface 11a of the LCOS 11 or on a back surface 11b of the LCOS 11 which back surface 11b is opposite to the light receiving surface 11a.

(Lid)

The lid 13 (i) is a lid having an optical window 13a which transmits light and (ii) constitutes, together with the body 14 (described later), the case in which the LCOS 11 is sealed. In Embodiment 1, the lid 13 has the optical window 13a and an optical window frame 13b.

The optical window 13a is constituted by a light-transmissive glass layer. Note that a material of the optical window 13a is not limited to glass, provided that the material transmits light having a desired wavelength. The material can be a light-transmissive resin.

The optical window frame 13b is a frame which holds the optical window 13a, and is made of metal. In Embodiment 1, the optical window 13a is connected to the optical window frame 13b by solder bonding, which is capable of maintaining airtightness. Alternatively, the optical window 13a can be connected to the optical window frame 13b, for example, by a connecting method using an adhesive, a connecting method using low-melting glass, or the like. The method of connecting the optical window 13a to the optical window frame 13b is not limited to the above methods, but can be selected as appropriate from connecting methods capable of maintaining airtightness.

A material of the optical window frame 13b is preferably metal due to weldability of the metal to a frame 14c (described later), but is not particularly limited, provided that the material is tightly connectable to the frame 14c.

In Embodiment 1, the lid 13 has the optical window 13a and the optical window frame 13b. Note, however, that a lid in accordance with an embodiment of the present invention can have no optical window frame 13b. In such a case, an optical window 13a should be configured such that an outer edge of the optical window 13a is connectable to a frame 14c (described later).

(Body)

In Embodiment 1, the body 14 includes a base substrate 14a, a plated layer 14b, and the frame 14c. The body 14 constitutes, together with the lid 13, the case in which the LCOS 11 is sealed.

The base substrate 14a is a member constituting a bottom of the body 14 and is made of ceramic. The plated layer 14b is provided at an outer edge of a surface of the base substrate 14a. A material of the base substrate 14a is not limited to ceramic, but can be determined as appropriate in consideration of various characteristics (e.g., heat conduction characteristic, weight, etc.) of the material.

The frame 14c is a member constituting side surfaces of the body 14 and is made of metal. The frame 14c is a cylindrical member which is constituted by four surfaces and whose openings are each rectangular. The base substrate 14a is welded to one of the two openings of the frame 14c via the plated layer 14b.

A height of the frame 14c is preferably uniform at any position. This configuration makes it easier to dispose the base substrate 14a and the optical window 13a in parallel to each other in a case where each of the base substrate 14a and the optical window 13a is connected to the frame 14c as described later.

One of the four surfaces constituting the frame 14c has an opening 14c1 provided therein. The opening 14c1 is an opening through which the FPC 16 is drawn from an inside to an outside of the body 14. A configuration for drawing the FPC 16 will be described later with reference to FIG. 2.

A material of the frame 14c is preferably metal due to weldability of the metal to the optical window frame 13b described above, but is not particularly limited, provided that the material is tightly connectable to the optical window frame 13b.

In Embodiment 1, the body 14 includes the base substrate 14a, the plated layer 14b, and the frame 14c. Note, however, that the body 14 can be constituted by a single member into which a base substrate and a frame are integrally formed.

(Connection of Members)

The LCOS 11 is connected to the lid 13 such that at least part of the effective region Ae overlaps with the optical window 13a. Note that the LCOS package 10 in accordance with Embodiment 1 employs a configuration in which the LCOS 11 is connected to the lid 13 such that the entire effective region Ae overlaps with the optical window 13a.

The lid 13 having the optical window 13a to which the LCOS 11 has been bonded is connected to the other one of the two openings of the frame 14c such that the lid 13 faces the base substrate 14a which has been welded to the frame 14c. The lid 13 can be connected to the frame 14c by any method that is capable of sealing a space which is formed by the lid 13 and the frame 14c. In Embodiment 1, since the optical window frame 13b and the frame 14c are both made of metal, the optical window frame 13b and the frame 14c are welded to each other by seam welding.

Note that, instead of the seam welding, it is possible to employ spot welding, soldering, brazing, or bonding using a resin. In a case where the optical window frame 13b or the frame 14c is made of resin, bonding using a resin can be employed as a connecting method.

The FPC 16 connected to the LCOS 11 is drawn out of the LCOS package 10 through the opening 14c1. The opening 14c1 is filled with a sealing resin 17 in order to seal the space formed by the lid 13 and the body 14. Note that, instead of the sealing resin 17, it is possible to employ solder as a material for sealing the opening 14c1. In such a case, local heating such as laser irradiation can be used to fill an inside of the opening 14c1 with solder.

This configuration allows a distance between the LCOS 11 and the lid 13 to be smaller, as compared with a case where the LCOS 11 is placed on the bottom of the body 14. That is, it is possible to reduce a possibility that dust enters between the LCOS 11 and the lid 13 in the space sealed by the case. Accordingly, the LCOS package 10 brings about an effect of suppressing, in an LCOS package including a case in which an LCOS 11 is sealed, a deterioration in performance of the LCOS 11 which deterioration may be caused by dust on a light path of light which enters the LCOS 11 or light which exits the LCOS 11.

Further, according to the configuration, the LCOS 11 is bonded to the optical window 13a of the lid 13 via an adhesive layer 12 which is light transmissive and provided on the effective region Ae. Accordingly, a relative positional relationship between the LCOS 11 and the optical window 13a, for example, a distance between the LCOS 11 and the optical window 13a only depends on a manufacturing error generated when the LCOS 11 is bonded to the optical window 13a.

Meanwhile, according to the solid-state image pickup device disclosed in Patent Literature 1, (1) the solid-state image pickup element is provided on the base substrate, (2) the resin frame is provided on the base substrate, and (3) the transparent plate is connected to an upper end of the resin frame. That is, the base substrate and the resin frame are provided between the solid-state image pickup element and the transparent plate. Accordingly, a relative positional relationship between the solid-state image pickup element and the transparent plate, for example, a distance between the solid-state image pickup element and the transparent plate is inevitably influenced by the base substrate and the resin frame. Specifically, the distance between the solid-state image pickup element and the transparent plate depends on accumulation of manufacturing errors of the base substrate and the resin frame, a manufacturing error generated when the solid-state image pickup element is connected to the base substrate, a manufacturing error generated when the base substrate is connected to the resin frame, and a manufacturing error generated when the transparent plate is connected to the resin frame.

As described above, the LCOS package 10 brings about an effect of facilitating uniformization of a light path length of light which enters the LCOS 11 or light which exits the LCOS 11, as compared with the solid-state image pickup device disclosed in Patent Literature 1.

In the LCOS package 10, the LCOS 11 is preferably bonded to the optical window 13a via the adhesive layer 12 which is light transmissive and provided on the effective region Ae.

According to the configuration, the adhesive layer which is light transmissive is provided between the effective region Ae and the optical window 13a of the lid 13. That is, no void is formed between the effective region Ae and the optical window 13a. This allows for no space for dust to enter between the effective region Ae and the optical window 13a. Accordingly, the LCOS package 10 brings about an effect of suppressing, in an LCOS package including a case in which an LCOS 11 is sealed, a deterioration in performance of the LCOS 11 which deterioration may be caused by dust on a light path of light which enters the LCOS 11 or light which exits the LCOS 11.

In the LCOS package 10 thus configured, the LCOS 11 is preferably spaced apart from the body 14 (see (b) of FIG. 1). This configuration makes it possible to prevent a heat conduction path from being formed between an external environment and the LCOS 11 through the body 14. This makes it possible to suppress a flow of heat from the external environment into the optical device and suppress a flow of heat out of the optical device into the external environment. Accordingly, an optical device package in accordance with an aspect of the present invention brings about an effect of suppressing an influence which is exerted on an optical device by a change in temperature of an external environment of the optical device package.

In a case where (i) the light receiving surface 11a including a surface of the effective region Ae and (ii) the optical window 13a are each constituted by a glass layer, a material of the adhesive layer 12 is preferably an epoxy resin, a silicone resin, an acrylic resin, or benzocyclobutene, which are light transmissive. These materials for the adhesive layer 12 each have a refractive-index within a range of not less than 0.9 and not more than 1.1 with respect to a refractive-index of the glass layer.

In a case where the material of the adhesive layer 12 has a refractive-index within the range of not less than 0.9 and not more than 1.1 with respect to the refractive-index of the glass layer, it is possible to suppress, to a level sufficient for practical use, light reflection which may occur at an interface between the adhesive layer 12 and the glass layer. That is, the LCOS package 10 having the configuration brings about an effect of suppressing light reflection which may occur at an interface between the optical window 13a and the adhesive layer 12 and at an interface between the adhesive layer 12 and the light receiving surface 11a of the LCOS 11. This consequently makes it possible to eliminate the need for an anti-reflection film for suppressing light reflection which may occur at each of the interfaces.

(Manufacturing Method)

The following description will discuss, with reference to FIG. 2, a method for manufacturing the LCOS package 10. (a) of FIG. 2 is a flow chart showing the method for manufacturing the LCOS package 10. (b) of FIG. 2 is a flow chart showing in detail a step of bonding the LCOS 11 to the optical window 13a in the method shown in (a) of FIG. 2.

The LCOS package 10 in accordance with Embodiment 1 employs a configuration in which the LCOS 11 is bonded to the optical window 13a via the adhesive layer 12 provided on the effective region Ae. In order to manufacture the LCOS package 10, the method for manufacturing the LCOS package 10 includes, as shown in (a) of FIG. 2, a connecting step (step S12) of connecting the LCOS 11 to the lid 13, a sealing step (step S13) of sealing the LCOS 11 by connecting the lid 13, to which the LCOS 11 has been connected, and the body 14 to each other.

First, in a step S11, the lid 13 is formed by bonding the optical window 13a to the optical window frame 13b.

Subsequently, in the step S12, the LCOS 11 is bonded to the optical window 13a via the adhesive layer 12 provided on the effective region Ae. Note that the FPC 16 has been connected to the LCOS 11 in advance.

In the step S13, the optical window frame 13b, to which the LCOS 11 has been bonded, and the frame 14c are welded to each other. Note that before the welding is carried out, the FPC 16 is drawn out of the body 14 through the opening 14c1. After the optical window frame 13b and the frame 14c are welded to each other, the opening 14c1 through which the FPC 16 is drawn is filled with the sealing resin 17. The LCOS package 10 is thus manufactured through the above steps.

In Embodiment 1, in order to prevent dust from adhering to the LCOS package 10, it is preferable to carry out each of the steps S12 and S13 in a clean environment (e.g., clean room) which has a function of removing dust floating in the air. In particular, it is preferable to carry out the step S12 in the clean environment.

In a case where at least the step S12 is carried out in the clean environment, it is possible to greatly reduce a possibility that dust is mixed into the adhesive layer 12. That is, it is possible to greatly reduce a possibility that dust enters a light path of the LCOS 11.

Note that, before the step S13 of welding between the optical window frame 13b and the frame 14c, it is possible to fill, with the sealing resin 17, the opening 14c1 through which the FPC 16 is drawn, and then carry out the step S13 under vacuum. In such a case, the welding between the optical window frame 13b and the frame 14c in the step S13 is preferably welding which enables airtight sealing.

In a case where the welding which enables airtight sealing is employed in the step S13, it is preferable to carry out the step S13 in a nitrogen atmosphere, a helium atmosphere, a mixed atmosphere of helium and nitrogen, or the like.

In a case where the step S13 is carried out in the nitrogen atmosphere, a space which is airtight-sealed by the lid 13 and the body 14 is filled with a nitrogen gas, and this makes it possible to prevent moisture from entering the space. Accordingly, it is possible to prevent the LCOS 11 from being deteriorated by moisture which has entered the space.

In a case where the step S13 is carried out in the helium atmosphere or in the mixed atmosphere of helium and nitrogen, a helium gas is introduced into the space which is airtight-sealed by the lid 13 and the body 14. In a case where the LCOS package 10 has a problem with airtightness, the helium gas leaks from the space. Thus, the airtightness of the LCOS package 10 can be checked by using a helium leak detector.

In a case where the welding which enables airtight sealing is employed in the step S13, the step S13 can be carried out under vacuum. In a case where the step S13 is carried out under vacuum, the space formed by the lid 13 and the body 14 is vacuumized. According to this configuration, a vacuum layer is formed between the LCOS 11 and the body 14. Accordingly, the LCOS package 10 brings about an effect of further suppressing an influence which is exerted on the LCOS 11 by a change in temperature of the external environment.

The following description will discuss in detail the step (step 12) of bonding the LCOS 11 to the optical window 13a (see (b) of FIG. 2).

In a step S121, an adhesive is applied to the optical window 13a. Note that a region to which the adhesive is applied is a region which overlaps with the effective region Ae when the LCOS 11 is bonded to the optical window 13a.

In a step S122, the LCOS 11 is placed on the optical window 13a such that the region to which the adhesive has been applied on the optical window 13a coincides with the effective region Ae.

In a step S123, the LCOS 11 placed on the optical window 13a is applied a pressure. By carrying out the step 123, the adhesive applied to the optical window 13a can have a uniform thickness. Accordingly, the light receiving surface 11a of the LCOS 11 and a surface of the optical window 13a which surface faces the LCOS 11 can be bonded to each other so as to be parallel to each other.

The optical window 13a on which the LCOS 11 has been placed is set in an oven. In a step S124, the adhesive applied to the optical window 13a is heat-cured by heating, by use of the oven, the optical window 13a on which the LCOS 11 has been placed. By carrying out the step S124, the adhesive applied to the optical window 13a becomes the adhesive layer 12 provided between the optical window 13a and the LCOS.

In the step S124, a pressure inside the oven is preferably preadjusted to zero before the adhesive applied to the optical window 13a is heat-cured. In a case where the adhesive is thus heat-cured under vacuum, the adhesive can be heat-cured while a bubble which may be generated in the adhesive is being removed (while the adhesive is being defoamed). In a case where a bubble remains in the adhesive layer 12, the bubble may block a light path of light which enters the effective region Ae or light which exits the effective region Ae. In a case where the adhesive is heat-cured while being defoamed, it is possible to reduce a possibility that a bubble remains in the adhesive layer 12.

Throughout the step S124, it is possible to continuously apply a pressure to the LCOS 11 placed on the optical window 13a. In a case where the adhesive is heat-cured while the LCOS 11 is applied a pressure, it is possible to reduce a possibility that a thickness of the adhesive layer 12 becomes non-uniform while the adhesive layer 12 is being heat-cured.

Note that the step S123 can be omitted in a case of employing a configuration in which a spacer is provided between the LCOS 11 and the optical window 13a as described later in Modified Example 1.

In the step S121, it is possible to employ a configuration in which the adhesive is applied to the effective region Ae of the LCOS 11, instead of applying the adhesive to the optical window 13a.

### Modified Example 1

The following description will discuss, with reference to FIG. 3, an LCOS package in accordance with Modified Example 1 of the LCOS package 10. (a) of FIG. 3 is an exploded perspective view illustrating a configuration of an LCOS package 20 in accordance with Modified Example 1. (b) of FIG. 3 is a cross-sectional view taken along a line A-A′ in (a) of FIG. 3 and illustrating a configuration of the LCOS package 20.

The LCOS package 20 differs from the LCOS package 10 in that the LCOS package 20 further includes a spacer 21 which is provided between an LCOS 11 and an optical window 13a. Accordingly, Modified Example 1 will discuss the spacer 21. Note that the same reference signs will be given to the same members as those of the LCOS package 10, and descriptions on such members will be omitted. Also in each of (a) and (b) of FIG. 3, a body 14 and an FPC 16 which are the same as those of the LCOS package 10 are omitted and not illustrated.

The spacer 21 is a spacer which is provided between the LCOS 11 and the optical window 13a and causes a light receiving surface 11a, which is a surface of the LCOS 11 which surface faces the optical window 13a, to be maintained parallel to a surface of the optical window 13a which surface faces the LCOS 11.

With the configuration, an adhesive is more easily heat-cured into an adhesive layer 12 while the light receiving surface 11a of the LCOS 11 is maintained parallel to the surface of the optical window 13a which surface faces the LCOS 11. In other words, the adhesive is more easily heat-cured into the adhesive layer 12 while a distance between the light receiving surface 11a of the LCOS 11 and the surface of the optical window 13a which surface faces the LCOS 11 is maintained constant. This uniformizes a light path length of light which enters the LCOS 11 or light which exits the LCOS 11, regardless of a position from which the light enters or a position from which the light exits. This brings about an effect of improving operation accuracy of the LCOS 11.

In Embodiment 1, the spacer 21 is an annular spacer which is provided so as to surround an effective region Ae. That is, the spacer 21 is provided on an ineffective region Aie. Accordingly, the spacer 21 does not block a light path of light which enters the effective region Ae or light which exits the effective region Ae, regardless of whether or not the spacer 21 is made of a light-transmissive material.

Alternatively, it is possible to employ a spacer having three or more protrusions having an identical height, instead of the spacer 21 having an annular shape. The three or more protrusions having an identical height can be separate members or can be connected to each other by an annular connecting member. Note that a shape of each of the three or more protrusions is not limited, but can be, for example, (i) a conical/pyramidal form such as a cone or a pyramid or (ii) a cylinder or a prism.

### Modified Example 2

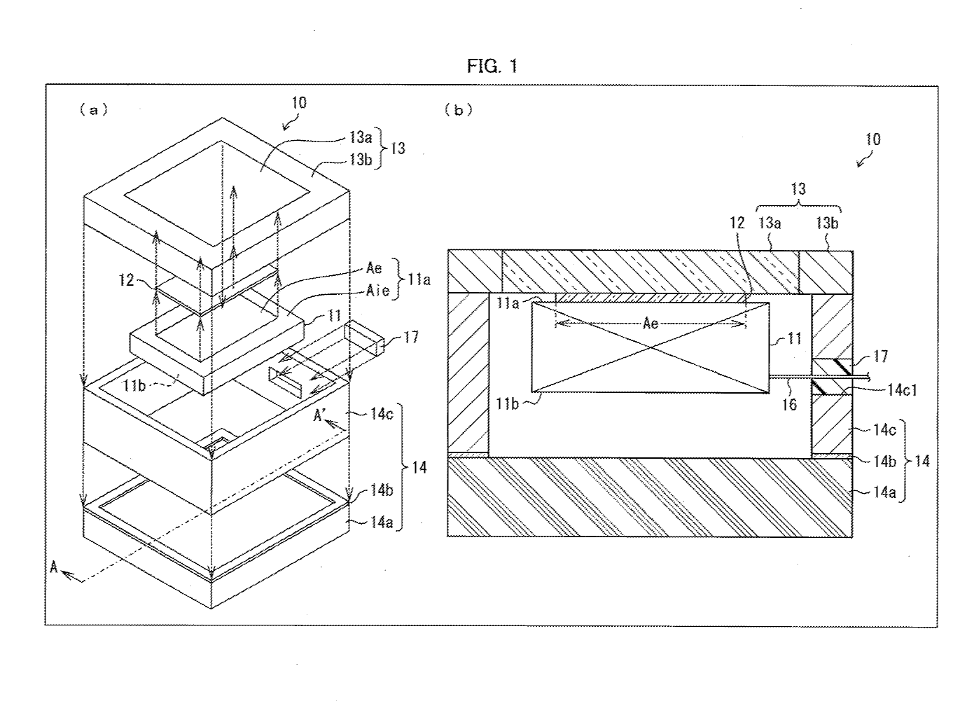

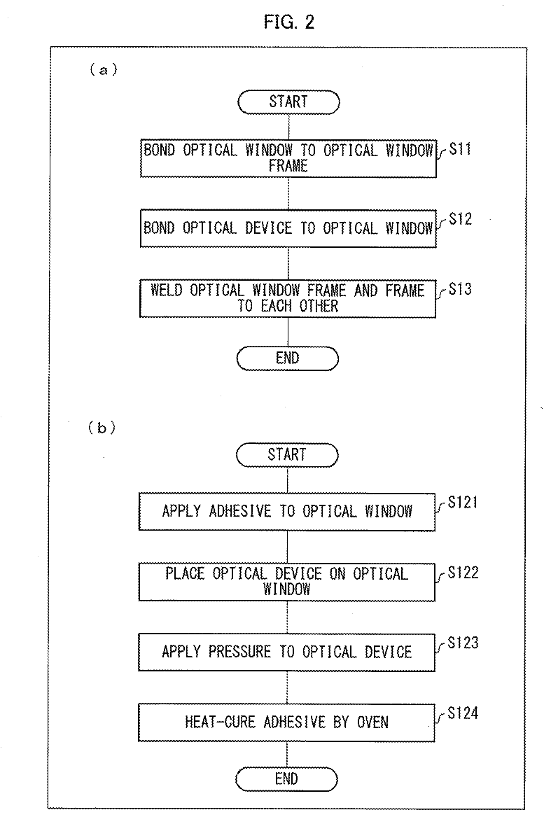

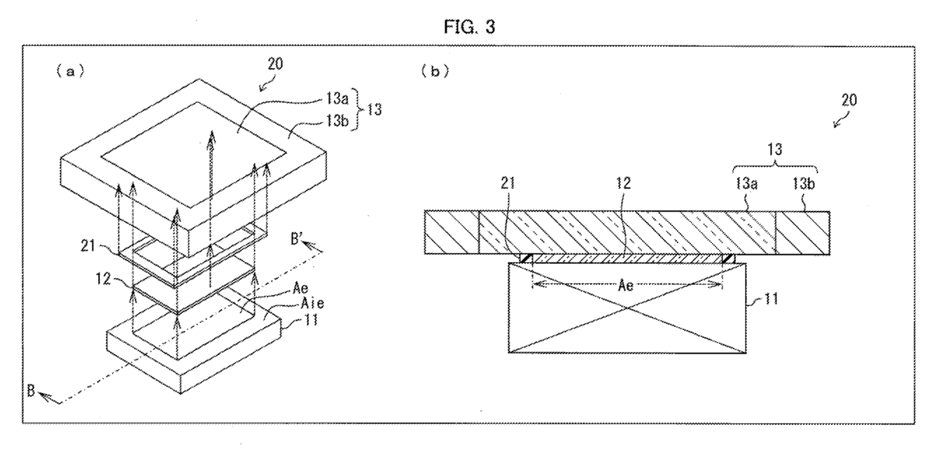

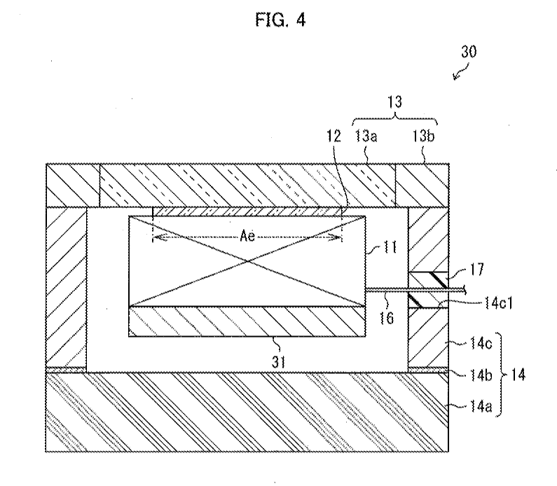

The following description will discuss, with reference to FIG. 4, an LCOS package in accordance with Modified Example 2 of the LCOS package 10. FIG. 4 is a cross-sectional view illustrating a configuration of an LCOS package 30 in accordance with Modified Example 2.

The LCOS package 30 differs from the LCOS package 10 in that the LCOS package 30 includes a heater 31. Accordingly, Modified Example 2 will discuss the heater 31. Note that the same reference signs will be given to the same members as those of the LCOS package 10, and descriptions on such members will be omitted.

As illustrated in FIG. 4, the heater 31 is provided on a surface of an LCOS 11 which surface is opposite to a surface of the LCOS 11 which surface includes an effective region Ae, and the LCOS 11 and the heater 31 are spaced apart from a body 14. Terminals included in the heater 31 are each connected to an FPC 16.

In Embodiment 1, the heater 31 is, but not limited to, a ceramic heater.

The LCOS 11 includes a liquid crystal layer, and thus, has a preferable temperature range as an operation temperature. Since the LCOS package 30 includes the heater 31, it is possible to increase a temperature of the LCOS 11 so that the temperature of the LCOS 11 reaches the preferable temperature range as an operation temperature.

Since the LCOS 11 and the heater 31 are spaced apart from the body 14, it is possible to prevent a heat conduction path from being formed between an external environment of the LCOS package 30 and the heater 31 through the body 14. This allows the LCOS package 30 to suppress a flow of heat from the external environment into the heater and suppress a flow of heat generated by the heater into the external environment. Accordingly, the LCOS package 30 brings about an effect of reducing power consumption of the heater.

Further, the heater 31 can include a temperature sensor which detects a temperature of the LCOS 11. With the configuration, the LCOS package 30 can control, by feedback control, the temperature of the LCOS 11 so that the temperature is within the preferable temperature range as an operation temperature. In doing so, since the LCOS 11 and the heater 31 are spaced apart from the body 14, the LCOS package 30 can suppress an influence which is exerted on the LCOS 11 and the heater 31 by a change in temperature of the external environment. Accordingly, the LCOS package 30 thus configured brings about an effect of improving stability of temperature control by the heater 31.

### Modified Examples 3 Through 6

The following description will discuss, with reference to (a) through (d) of FIG. 5, LCOS packages in accordance with respective Modified Examples 3 through 6 of the LCOS package 10. (a) of FIG. 3 is a cross-sectional view illustrating a configuration of an LCOS package 40 in accordance with Modified Example 3. (b) of FIG. 3 is a cross-sectional view illustrating a configuration of an LCOS package 50 in accordance with Modified Example 4. (c) of FIG. 3 is a cross-sectional view illustrating a configuration of an LCOS package 60 in accordance with Modified Example 5. (d) of FIG. 3 is a cross-sectional view illustrating a configuration of an LCOS package 70 in accordance with Modified Example 6.

The LCOS packages 40 through 70 each differ from the LCOS package 10 in how an LCOS 11 and a window 13 are connected to each other. Accordingly, each of Modified Examples 3 through 6 will discuss how the LCOS 11 and the window 13 are connected to each other. Note that the same reference signs will be given to the same members as those of the LCOS package 10, and descriptions on such members will be omitted. Also in each of (a) through (d) of FIG. 5, a body 14 and an FPC 16 which are the same as those of the LCOS package 10 are omitted and are not illustrated.

As illustrated in (a) of FIG. 5, the LCOS package 40 employs a double-sided adhesive tape 42, instead of the adhesive layer 12. Specifically, the LCOS 11 of the LCOS package 40 is connected to the lid 13, more specifically, to an optical window 13a via the double-sided adhesive tape which is light transmissive and provided on an effective region Ae.

According to the LCOS package 40, since the double-sided adhesive tape 42 is provided between the LCOS 11 and the optical window 13a, it becomes easier to cause a surface of the LCOS 11 which surface faces the optical window 13a to be maintained parallel to a surface of the optical window 13a which surface faces the LCOS 11, as compared with a case where no double-sided adhesive tape is provided between the LCOS 11 and the optical window 13a. In other words, it becomes easier to maintain constant a distance between a light receiving surface 11a of the LCOS 11 and the surface of the optical window 13a which surface faces the LCOS 11. This uniformizes a light path length of light which enters the LCOS 11 or light which exits the LCOS 11, regardless of a position from which the light enters or a position from which the light exits. This brings about an effect of improving operation accuracy of the LCOS 11.

It is preferable to employ, as a light-transmissive material constituting the double-sided adhesive tape, a material having a refractive-index which is equivalent to that of a glass layer. With the configuration, the LCOS package 40 brings about an effect of suppressing light reflection which may occur at an interface between the optical window 13a and the double-sided adhesive tape 42 and at an interface between the double-sided adhesive tape 42 and the light receiving surface of the LCOS 11.

As illustrated in (b) of FIG. 5, the LCOS 11 of the LCOS package 50 is connected to the lid 13, more specifically, to an optical window 13a via both of (1) an adhesive layer 52a which is provided so as to cover an effective region Ae and is light transmissive and (2) an adhesive layer 52b which is provided in an ineffective region Aie surrounding the effective region Ae. The adhesive layer 52a is an adhesive layer corresponding to the adhesive layer 12 of the LCOS package 10.

With the configuration, it is possible to increase a bonding area which is an area of regions in which the respective adhesive layers (52a, 52b) are provided, as compared with a case where the LCOS 11 is bonded to the optical window 13a only via the adhesive layer 12. Accordingly, the LCOS package 50 brings about an effect of increasing bonding strength between the LCOS 11 and the lid 13.

Note that the adhesive layer 52a is preferably provided in a region larger than the effective region Ae and encompassing the effective region Ae. A gap between each side of the adhesive layer 52a and a corresponding side of the effective region Ae preferably exceeds t×tan θ, where t indicates a thickness of the adhesive layer 52a and θ indicates an incident angle of incident light. The configuration makes it possible to prevent the adhesive layer 52b from blocking incident light which enters an outer edge of the effective region Ae.

As illustrated in (c) of FIG. 5, the LCOS 11 of the LCOS package 60 is connected to the lid 13, more specifically, to an optical window 13a via an adhesive layer 62 which (i) has an annular shape surrounding an effective region Ae and (ii) is provided on an ineffective region Aie surrounding the effective region Ae. That is, a void is formed between the effective region Ae and the optical window 13a.

With the configuration, the void formed between the effective region Ae and the optical window 13a has a height equivalent to a thickness of the adhesive layer 62. In a case where the step S13 shown in (a) of FIG. 2 is carried out in the atmosphere, the void is filled with air. A thermal conductivity of the void, i.e., a thermal conductivity of the air, is lower than that of the adhesive layer 12. Accordingly, the LCOS package 60 brings about an effect of suppressing an influence which is exerted on the effective region Ae of the LCOS 11 by a change in temperature of an external environment, as compared with the LCOS package 10.

In a case where the LCOS package 60 is manufactured, it is preferable to carry out the step S13 under vacuum. In such a case, welding between an optical window frame 13b and the body 14 in the step S13 is carried out preferably by the welding which enables airtight sealing. Carrying out the step S13 in this manner makes it possible to vacuumize the void formed between the effective region Ae and the optical window 13a. Since a thermal conductivity in vacuum is lower than that in air, it is possible to further suppress an influence which is exerted on the effective region Ae of the LCOS 11 by a change in temperature of the external environment.

In the LCOS package 60, the void formed between the effective region Ae and the optical window 13a is surrounded by the adhesive layer 62. This allows the LCOS package 60 to prevent dust from entering the void. Accordingly, the LCOS package 60 brings about an effect of suppressing a deterioration in performance of an optical device which deterioration may be caused by dust on a light path of light which enters an LCOS 11 or light which exits the LCOS 11, in an LCOS package including a case in which the LCOS 11 is sealed.

Note that it is possible to provide the adhesive layer 62 only in a part of an annular region surrounding the effective region Ae. For example, the adhesive layer 62 can be provided only at four corners of the ineffective region Aie in the annular region so as to bond the four corners of the ineffective region Aie. As described above, the height of the adhesive layer 62 is equivalent to the thickness of the adhesive layer 62 and is lower than a height of a void which is formed between the solid-state image pickup element and the transparent plate in the solid-state image pickup device disclosed in Patent Literature 1. Accordingly, the LCOS package 60 thus configured can also reduce a possibility that dust enters the void. Thus, the LCOS package 60 brings about an effect of suppressing a deterioration in performance of an optical device which deterioration may be caused by dust on a light path of light which enters an LCOS 11 or light which exits the LCOS 11, in an LCOS package including a case in which the LCOS 11 is sealed.

In the ineffective region Aie, the adhesive layer 62 is preferably provided in a region other than a region near the effective region Ae. The region near the effective region Ae is an annular region which surrounds the effective region Ae and has a width of not less than t×tan θ, where t indicates the thickness of the adhesive layer 62 and θ indicates an incident angle of incident light. The configuration makes it possible to prevent the adhesive layer 62 from blocking incident light which enters an outer edge of the effective region Ae.

Note that in a case where an adhesive layer provided on the ineffective region Aie is employed as with the LCOS package 60, it is possible to employ a configuration in which the LCOS 11 is connected to an optical window frame 73b of a lid 73 via an adhesive layer 72 which is provided on an ineffective region Aie of the LCOS 11, as with the LCOS package 70 illustrated in (d) of FIG. 5. The LCOS package 70 brings about an effect similar to that of the LCOS package 60.

As a modified example of the LCOS package 70, it is possible to employ a configuration in which an LCOS 11 is connected to an optical window 73a and an optical window frame 73b of a lid 73 via an adhesive layer 72 which is provided on an ineffective region Aie of the LCOS 11.

Note that in order to form the adhesive layers 52b, 62, and 72 on the ineffective regions Aie, it is possible to employ an adhesive containing a filler in the LCOS packages 50, 60, and 70, respectively. The adhesive layer made of the adhesive containing a filler can achieve higher bonding strength as compared with an adhesive layer made of an adhesive containing no filler. Accordingly, each of the LCOS packages 50, 60, and 70 thus configured brings about an effect of further increasing bonding strength between the LCOS 11 and the lid 13. The increase in bonding strength between the LCOS 11 and the lid 13 can lead to an increase in impact resistance and durability of the LCOS package.

### Modified Example 7

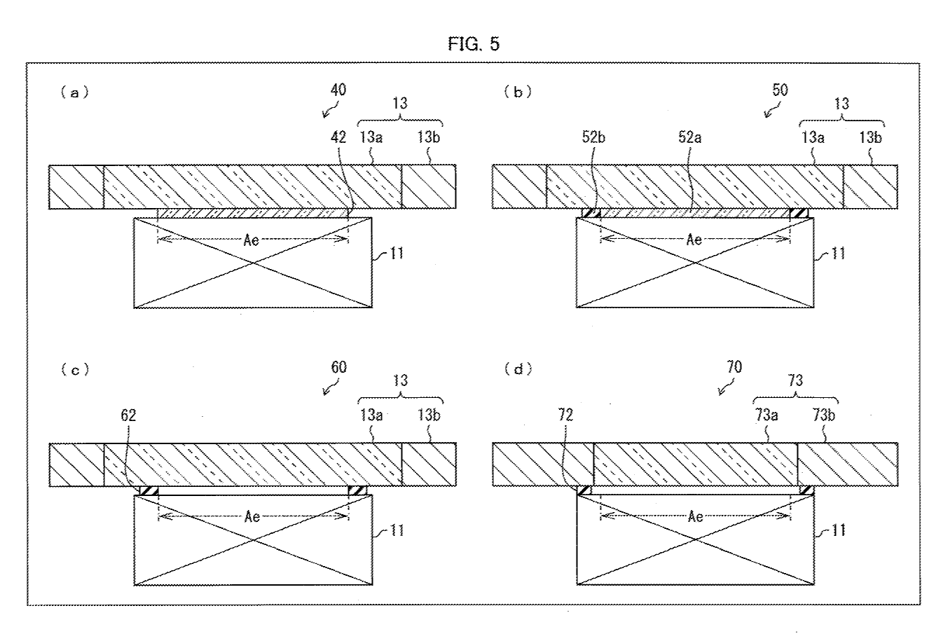

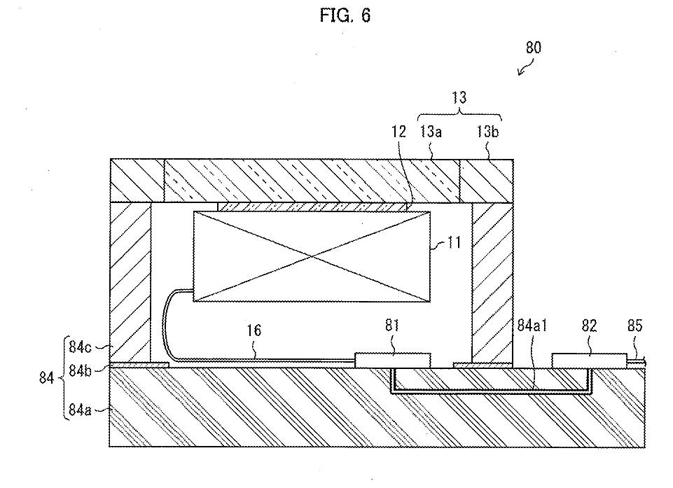

The following description will discuss, with reference to FIG. 6, an LCOS package in accordance with Modified Example 7 of the LCOS package 10. FIG. 6 is a cross-sectional view illustrating a configuration of an LCOS package 80 in accordance with Modified Example 7.

The LCOS package 80 differs from the LCOS package 10 in a configuration for drawing, out of a case, a wire which connects an LCOS 11 to a control substrate. Accordingly, Modified Example 7 will discuss the configuration for drawing, out of the case, the wire which connects the LCOS 11 to the control substrate. Note that the same reference signs will be given to the same members as those of the LCOS package 10, and descriptions on such members will be omitted.

As illustrated in FIG. 6, the LCOS package 80 includes a case 84, instead of the body 14 of the LCOS package 10. The case 84 includes a base substrate 84a, a plated layer 84b, and a frame 84c. The base substrate 84a, the plated layer 84b, and the frame 84c correspond to the base substrate 14a, the plated layer 14b, and the frame 14c, respectively, of the LCOS package 10.

The base substrate 84a is a multilayer ceramic substrate which is constituted by a stack of a plurality of substrates (ceramic substrates) which are made of ceramic.

A connector 81 is provided on a surface of the base substrate 84a which surface is located inside the case 84, and a connector 82 is provided on a surface of the base substrate 84a which surface is located outside the case 84.

The connector 81 is electrically connected to the connector 82 through a conductive path 84al provided in the base substrate 84a. The conductive path 84al is constituted by (i) a conductive film which is provided on a surface of a ceramic substrate located in an intermediate layer of the base substrate 84a and (ii) vias which are provided in a thickness direction of the base substrate 84a at respective both ends of the conductive film. The vias are exposed to the surface of the base substrate 84a and electrically conductive with the conductive film provided in the intermediate layer of the base substrate 84a. Accordingly, the connector 81 which is connected to one of the vias is electrically conductive with the connector 82 which is connected to the other one of the vias.

An FPC 16 connects the LCOS 11 to the connector 81. One end of an FPC 85 is connected to the connector 82. By connecting the other end of the FPC 85 to the control substrate, it is possible to connect the LCOS 11 to the control substrate.

Unlike the LCOS package 10, the LCOS package 80 can eliminate the need to form an opening 14c1 in a body 14 in advance, draw the FPC 16 through the opening 14c1, and then seal, with a sealing resin 17, the opening 14c1 through which the FPC 16 is drawn.

### Modified Example 8

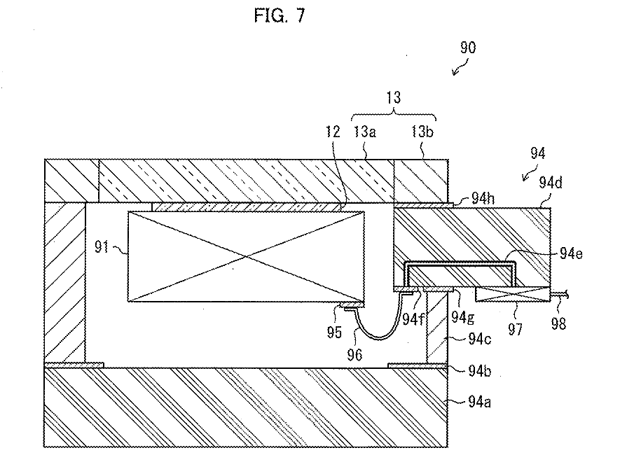

The following description will discuss, with reference to FIG. 7, an LCOS package in accordance with Modified Example 8 of the LCOS package 10. FIG. 7 is a cross-sectional view illustrating a configuration of an LCOS package 90 in accordance with Modified Example 8.

The LCOS package 90 differs from the LCOS package 80 in a configuration for drawing, out of a case, a wire which connects an LCOS 11 to a control substrate. Accordingly, Modified Example 8 will discuss a configuration for drawing, out of a case, a wire which connects an LCOS 91 to a control substrate. Note that the same reference signs will be given to the same members as those of the LCOS package 10, and descriptions on such members will be omitted.

As illustrated in FIG. 7, the LCOS package 90 includes a case 94, instead of the case 84 of the LCOS package 80. An electrode 95 which is constituted by a conductive film is provided on a back surface of the LCOS 91.

The case 94 includes a first base substrate 94a, a plated layer 94b, a frame 94c, a second base substrate 94d, a conductive path 94e, a pad 94f, a plated layer 94g, and a plated layer 94h and is obtained by deforming the case 84 of the LCOS package 80.

The first base substrate 94a and the frame 94c are welded to each other via the plated layer 94b. The second base substrate 94d and the frame 94c are welded to each other via the plated layer 94g. The second base substrate 94d and an optical window frame 13b are welded to each other via the plated layer 94h. The LCOS package 90 thus configured can seal the LCOS 91 in a space formed by the case 94 and a lid 13.

The pad 94f which is constituted by a conductive film is provided on a surface of the second base substrate 94d which surface (i) faces the first base substrate 94a and (ii) is located inside the case 94. A connector 97 is provided on a surface of the second base substrate 94d which surface (i) faces the first base substrate 94a and (ii) is located outside the case 94.

The pad 94f is electrically connected to the connector 97 through the conductive path 94e provided in the second base substrate 94d. The conductive path 94e is similar in configuration to the conductive path 84a1 provided in the base substrate 84a. Accordingly, the pad 94f and the connector 97 are electrically conductive with each other.

A bonding wire 96 is a wire formed by carrying out wire-bonding between the electrode 95 and the pad 94f. That is, the electrode 95 is electrically connected to the pad 94f via the bonding wire 96. One end of an FPC 98 is connected to the connector 97. By connecting the other end of the FPC 98 to the control substrate, it is possible to connect the LCOS 91 to the control substrate.

According to the LCOS package 90, it is possible to electrically connect the LCOS 91 to the conductive path 94e via the bonding wire 96 formed by the wire bonding. In other words, according to the LCOS package 90, the FPC 16 and the connector 81 can be omitted, so that a manufacturing step can be simplified, as compared with the LCOS package 80.

### Embodiment 2

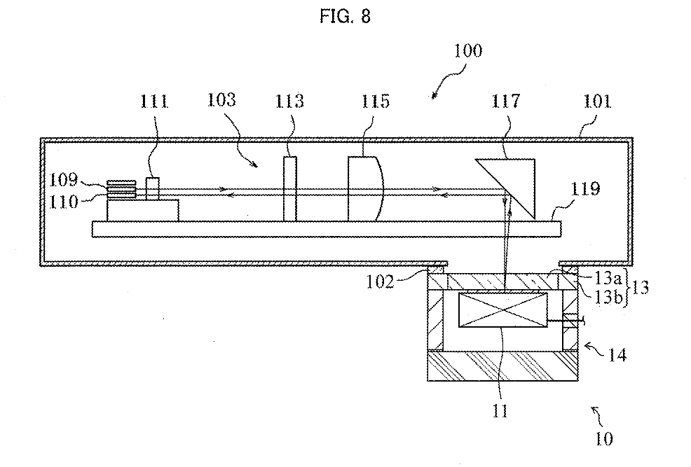

The following description will discuss, with reference to FIG. 8, an optical switch in accordance with Embodiment 2 of the present invention. FIG. 8 is a cross-sectional view illustrating a configuration of an optical switch 100 in accordance with Embodiment 2. The optical switch 100 includes an LCOS package 10 in accordance with Embodiment 1. Note, however, that the LCOS package included in the optical switch 100 is not limited to the LCOS package 10, but can be any of the LCOS packages 20 through 90 in accordance with respective modified examples of the present invention.

As illustrated in FIG. 8, the optical switch 100 includes a case 101, an optical system 103 provided in the case 101, and the LCOS package 10. The following description will first discuss a configuration of the case 101 and how the case 101 and the LCOS package 10 are connected to each other, and then discuss a configuration of the optical system 103.

(Case 101 and LCOS Package 10)

The case 101 is a case for housing therein the optical system 103. The case 101 has an opening for optically coupling the optical system 103 and the LCOS package 10 to each other. A material of the case 101 can be, but not particularly limited to, metal, resin, or the like.

The LCOS package 10 is connected, via a connecting member, to the case 101 such that (i) an optical window 13a of a lid 13 overlaps the opening of the case 101 and (ii) an incident surface of the optical window 13a from which incident surface light enters is parallel to a surface of the case 101 which surface surrounds the opening. In Embodiment 2, an optical window frame 13b is bonded to the case 101 via an adhesive layer 102 which is the connecting member. With the configuration, the adhesive layer 102 maintains the incident surface of the optical window 13a parallel to the surface of the case 101 which surface surrounds the opening.

Alternatively, it is possible to connect the LCOS package 10 to an optical window 107 or the case 101, for example, by connecting the optical window frame 13b of the lid 13 to the case 101 by use of a bolt which is the connecting member. Between the optical window frame 13b and the case 101, a spacer (not illustrated in FIG. 8) is provided so as to cause a surface of the optical window 13a which surface faces the optical window 107 to be maintained parallel to a surface of the optical window 107 which surface faces the optical window 13a.

As described above, the optical switch 100 employs, as a reference surface for connecting the LCOS package 10 to the case 101, the surface of the optical window 13a which surface faces the optical window 107, instead of employing one of surfaces of a body 14 of the LCOS package 10. With the configuration, a light receiving surface of an LCOS 11 is parallel to one surface of the optical window 13a and the other surface of the optical window 13a is parallel to the surface of the optical window 107 which surface faces the optical window 13a. Accordingly, it becomes easier to cause the light receiving surface of the LCOS 11 to be maintained parallel to the surface of the optical window 107 which surface faces the optical window 13a, as compared with a case where one of the surfaces of the body 14 serves as the reference surface. This brings about an effect of easily suppressing a variation in light path length of light which enters the light receiving surface of the LCOS 11, even in a case where a position from which the light enters the light receiving surface of the LCOS 11 changes.

(Optical System 103)

The following description will discuss the optical system 103 which is housed in the case 101. The optical system 103 includes an input port 109, output ports 110, a microlens array 111, a dispersing section 113, a light collecting device 115, a mirror 117, and an optical base 119. The input port 109, the output ports 110, the microlens array 111, the dispersing section 113, the light collecting device 115, and the mirror 117 are each fixed on the optical base 119 which is made of light-transmissive glass.

The input port 109 is a port through which multiplexed light is inputted as input light to the optical switch 100. The output ports 110 are each a port through which output light whose path has been switched by the LCOS 11 of the LCOS package 10 is outputted from the optical switch 100. The input port 109 and the output ports 110 are each constituted by an optical fiber.

In the optical switch 100, a port array is constituted by at least one input port 109 and a plurality of output ports 110 in combination. Note that FIG. 8 illustrates only one input port 109 and two output ports 110 of the port array thus configured.

The microlens array 111 is configured such that microlenses corresponding to the respective input port 109 and output ports 110 which constitute the port array are arranged in an array. The microlens array 111 (i) converts, into parallel light flux, the input light inputted to the optical switch 100 through the input port 109 and (ii) focuses, onto the output port 110, the output light whose path has been switched by the LCOS 11.

The dispersing section 113 is for causing the input light, which has been converted into the parallel light flux by the microlens array 111, to be dispersed into light beams according to wavelengths. The dispersing section 113 can be a transmissive dispersion device, or a reflective diffraction grating. In a case where the reflective diffraction grating is employed as the dispersing section 113, a configuration of the optical system 103 can be modified so as to be suitable for the reflective diffraction grating.

The light collecting device 115 collects the light beams, into which the incident light has been dispersed by the dispersing section 113 according to wavelengths. For example, the light collecting device 11 can be a convex lens.

The mirror 117 (i) guides, towards the LCOS 11 of the LCOS package 10, the input light which has been collected by the light collecting device 115 and (ii) guides, towards the output ports 110, the output light whose path has been switched by the LCOS 11.

The input light enters the LCOS 11 of the LCOS package 10 from the optical system 103 thus configured. The LCOS 11 (i) controls alignment of a liquid crystal layer so as to switch a light path of the input light inputted from the optical system 103 and (ii) reflects the input light so as to output thus reflected light to the optical system 103 as the output light.

The optical switch 100 thus configured (i) causes input light inputted through the input port 109 to be dispersed according to wavelengths and (ii) switches a light path of a light beam having a desired wavelength, so that the optical switch 100 can output, as output light to any of the output ports 110, the light beam having a desired wavelength.

### CONCLUSION

An optical device package in accordance with Embodiment 1 is an optical device package including a case in which an optical device is sealed, including a lid having an optical window which transmits light, the optical device being connected to the lid such that at least part of an effective region of the optical device overlaps with the optical window.

The configuration allows a distance between the optical device and the lid to be smaller, as compared with a case where the optical device is placed on a bottom of the case. That is, it is possible to reduce a possibility that dust enters between the optical device and the lid in a space sealed by the case. Accordingly, an optical device package having the configuration brings about an effect of suppressing, in an optical device package including a case in which an optical device is sealed, a deterioration in performance of the optical device which deterioration may be caused by dust on a light path of light which enters the optical device or light which exits the optical device.

According to a solid-state image pickup device disclosed in Patent Literature 1, a base substrate and a resin frame are provided between a solid-state image pickup element and a transparent plate. Accordingly, an error related to a relative positional relationship (e.g., a distance between the solid-state image pickup element and the transparent plate) between the solid-state image pickup element and the transparent plate is accumulation of an error generated when the solid-state image pickup element is connected to the base substrate, an error generated when the resin frame is connected to the base substrate, and an error generated when the transparent plate is connected to the resin frame. Meanwhile, with the configuration, since the optical device is connected to the lid, an error related to a relative positional relationship (e.g., a distance between the optical device and the optical window) between the optical device and the optical window is caused only by a manufacturing error generated when the optical device is connected to the lid. Accordingly, the configuration makes it easier to uniformize a light path length of light which enters the optical device or light which exits the optical device, as compared with the solid-state image pickup device disclosed in Patent Literature 1.

The optical device package in accordance with Embodiment 1 is preferably configured such that the optical device is connected to the lid via an adhesive layer which is light transmissive and provided on the effective region.

With the configuration, the adhesive layer which is light transmissive is provided between the effective region of the optical device and the lid, more specifically, between the effective region and the optical window. That is, no void is formed between the effective region and the optical window. This allows for no space for dust to enter between the effective region and the optical window. Accordingly, an optical device package having the configuration brings about an effect of suppressing a deterioration in performance of an optical device which deterioration may be caused by dust on a light path of light which enters the optical device or light which exits the optical device.

The optical device package in accordance with Embodiment 1 is preferably configured such that the optical device is connected to the lid via both of (i) the adhesive layer which is light transmissive and provided on the effective region and (ii) an adhesive layer which is provided on an ineffective region surrounding the effective region.

With the configuration, it is possible to increase a bonding area which is an area of regions in which the respective adhesive layers are provided, as compared with a case where the optical device is bonded to the lid only via the adhesive layer provided on the effective region. Accordingly, an optical device package having the configuration brings about an effect of increasing bonding strength between an optical device and a lid.

The optical device package in accordance with Embodiment 1 is preferably configured such that the optical window and a surface of the effective region are each constituted by a glass layer; and the adhesive layer which is provided on the effective region is made of an epoxy resin, a silicone resin, an acrylic resin, or a benzocyclobutene.

With the configuration, the adhesive layer has a refractive-index which is equivalent to those of (i) the surface of the effective region of the optical device and (ii) the optical window. Accordingly, an optical device package having the configuration brings about an effect of suppressing light reflection which may occur at an interface between an optical window and an adhesive layer and at an interface between the adhesive layer and a light receiving surface of an optical device.

The optical device package in accordance with Embodiment 1 is preferably configured such that the optical device is connected to the lid via an adhesive layer which is provided on an ineffective region surrounding the effective region; and a void is formed between the effective region and the optical window.

With the configuration, a void which has a height equivalent to a thickness of the adhesive layer is formed between the effective region and the optical window. The void has a thermal conductivity lower than that of the adhesive layer. Accordingly, an optical device package having the configuration brings about an effect of suppressing an influence which is exerted on an effective region by a change in temperature of an external environment of the optical device package.

The optical device package in accordance with Embodiment 1 is preferably configured such that the adhesive layer which is provided on the ineffective region is made of an adhesive containing a filler.

The adhesive layer containing a filler can achieve higher bonding strength as compared with an adhesive layer containing no filler. Accordingly, the configuration brings about an effect of further increasing bonding strength between the optical device and the lid.

The optical device package in accordance with Embodiment 1 is preferably configured to further include a spacer which is provided between the optical device and the optical window and causes a surface of the optical device which surface faces the optical window to be maintained parallel to a surface of the optical window which surface faces the optical device.

With the configuration, it becomes easier to cause the surface of the optical device which surfaces faces the optical window to be maintained parallel to the surface of the optical window which surface faces the optical device. This uniformizes a light path length of light which enters the optical device or light which exits the optical device, regardless of a position from which the light enters or a position from which the light exits. This brings about an effect of improving operation accuracy of the optical device.

The optical device package in accordance with Embodiment 1 is preferably configured such that the optical device is connected to the lid via a double-sided adhesive tape which is light transmissive and provided on the effective region.

With the configuration, the double-sided adhesive tape is provided between the optical device and the optical window. According to an optical device package having the configuration, it becomes easier to cause a surface of an optical device which surface faces an optical window to be maintained parallel to a surface of the optical window which surface faces the optical device, as compared with a case where no double-sided adhesive tape is provided between the optical device and the optical window. This uniformizes a light path length of light which enters the optical device or light which exits the optical device, regardless of a position from which the light enters or a position from which the light exits. This brings about an effect of improving operation accuracy of the optical device.

The optical device package in accordance with Embodiment 1 is preferably configured to further include a body which, together with the lid, constitutes the case, the optical device being spaced apart from the body.

The configuration makes it possible to prevent a heat conduction path from being formed between the external environment of the optical device package and the optical device through the body. This makes it possible to suppress a flow of heat from the external environment into the optical device through the body and suppress a flow of heat out of the optical device into the external environment through the body. Accordingly, an optical device package having the configuration brings about an effect of suppressing an influence which is exerted on an optical device by a change in temperature of an external environment.

The optical device package in accordance with Embodiment 1 is preferably configured to further include a heater provided on a surface of the optical device which surface is opposite to a surface of the optical device which surface includes the effective region, each of the optical device and the heater being spaced apart from the body.

In a case where the optical device has a preferable temperature range as an operation temperature (e.g., in a case where the optical device is an LCOS device), the configuration allows, by use of the heater, increasing a temperature of the optical device so that the temperature of the optical device reaches the preferable temperature range. Further, the configuration makes it possible to prevent a heat conduction path from being formed between the external environment and the heater through the body. This allows the optical device package to suppress a flow of heat from the external environment into the heater through the body and suppress a flow of heat generated by the heater into the external environment through the body. Accordingly, an optical device package having the configuration brings about an effect of reducing power consumption of a heater.

An optical switch in accordance with Embodiment 2 is preferably configured to include any of the optical device packages in accordance with Embodiment 1.

With the configuration, the optical switch in accordance with Embodiment 2 brings about an effect similar to that of the optical device package in accordance with Embodiment 1.

A method for manufacturing an optical device package in accordance with Embodiment 1 is a method for manufacturing an optical device package including a case in which an optical device is sealed, the case including a body and a lid having an optical window which transmits light, the method including the steps of: connecting the optical device to the lid such that at least part of an effective region of the optical device overlaps with the optical window; and sealing the optical device by connecting the case to the lid to which the optical device has been connected.

With the configuration, the method for manufacturing an optical device package in accordance with Embodiment 1 brings about an effect similar to that of the optical device package in accordance with Embodiment 1.

The present invention is not limited to the embodiments, but can be altered by a skilled person in the art within the scope of the claims. An embodiment derived from a proper combination of technical means each disclosed in a different embodiment is also encompassed in the technical scope of the present invention.

### INDUSTRIAL APPLICABILITY

The present invention is applicable to an optical device package including a case in which an optical device is sealed.

### REFERENCE SIGNS LIST

10, 20, 30, 40, 50, 60, 70, 80, 90: LCOS package (optical device package)
11, 91: LCOS (optical device)
11a: Light receiving surface
11b: Back surface
12, 52a, 52b, 62, 72: Adhesive layer
13, 73: Lid
13a, 73a: Optical window
13b, 73b: Optical window frame
14, 84, 94: Body
14a, 84a: Base substrate
14b, 84b, 94b, 94g, 94h: Plated layer
14c, 84c, 94c: Frame
81, 82, 97: Connector
16, 85, 98: FPC
17: Sealing resin
21: Spacer
31: Heater
42: Double-sided adhesive tape
94a: First base substrate
94d: Second base substrate
95: Electrode
96: Bonding wire

1. An optical device package including a case in which an optical device is sealed, comprising a lid having an optical window which transmits light,
the optical device being connected to the lid such that at least part of an effective region of the optical device overlaps with the optical window.

2. The optical device package as set forth in claim 1, wherein the optical device is connected to the lid via an adhesive layer which is light transmissive and provided on the effective region.

3. The optical device package as set forth in claim 2, wherein the optical device is connected to the lid via both of (i) the adhesive layer which is light transmissive and provided on the effective region and (ii) an adhesive layer which is provided on an ineffective region surrounding the effective region.

4. The optical device package as set forth in claim 2, wherein:
the optical window and a surface of the effective region are each constituted by a glass layer; and
the adhesive layer which is provided on the effective region is made of an epoxy resin, a silicone resin, an acrylic resin, or a benzocyclobutene.

5. The optical device package as set forth in claim 1, wherein:
the optical device is connected to the lid via an adhesive layer which is provided on an ineffective region surrounding the effective region; and
a void is formed between the effective region and the optical window.

6. The optical device package as set forth in claim 3, wherein the adhesive layer which is provided on the ineffective region is made of an adhesive containing a filler.

7. An optical device package as set forth in claim 1, further comprising a spacer which is provided between the optical device and the optical window and causes a surface of the optical device which surface faces the optical window to be maintained parallel to a surface of the optical window which surface faces the optical device.

8. The optical device package as set forth in claim 1, wherein the optical device is connected to the lid via a double-sided adhesive tape which is light transmissive and provided on the effective region.

9. An optical device package as set forth in claim 1, further comprising a body which, together with the lid, constitutes the case,
the optical device being spaced apart from the body.

10. An optical device package as set forth in claim 9, further comprising a heater provided on a surface of the optical device which surface is opposite to a surface of the optical device which surface includes the effective region,
each of the optical device and the heater being spaced apart from the body.

11. An optical switch comprising an optical device package recited in claim 1.

12. A method for manufacturing an optical device package including a case in which an optical device is sealed, the case including a body and a lid having an optical window which transmits light,
said method comprising the steps of:
connecting the optical device to the lid such that at least part of an effective region of the optical device overlaps with the optical window; and
sealing the optical device by connecting the case to the lid to which the optical device has been connected.
